(19) United States
(12) Patent Application Publication
(10) Pub. No.: US 2014/0140017 A1
(43) Pub. Date: May 22, 2014

(54) ELECTRONIC DEVICE WITH CARD BRACKET

(71) Applicants: HON HAI PRECISION INDUSTRY CO., LTD., New Taipei (TW); HONG FU JIN PRECISION INDUSTRY (ShenZhen) CO., LTD., Shenzhen (CN)

(72) Inventor: BAO-QUAN SHI, Shenzhen (CN)

(73) Assignees: HON HAI PRECISION INDUSTRY CO., LTD., New Taipei (TW); HONG FU JIN PRECISION INDUSTRY (ShenZhen) CO., LTD., Shenzhen (CN)

(21) Appl. No.: 13/958,570

(22) Filed: Aug. 4, 2013

(30) Foreign Application Priority Data
Nov. 21, 2012 (CN) 2012104747185

(51) Int. Cl. H05K 7/14

(52) U.S. Cl. CPC H05K 7/1404
USPC 361/748

(57) ABSTRACT

An electronic device includes a circuit board and a card bracket. The card bracket includes a base panel and a pair of latching pieces extending from opposite sides of the base panel. Each of the pair of latching pieces includes a resilient arm extending perpendicularly from the base panel and a latching flange extending from the resilient arm at an angle that is slightly less than 90 degrees. The latching piece includes a curling edge. A circuit board includes a pair of mounting holes corresponding to the pair of latching flanges. The resilient arm is deformable and movable between a first position and a second position. In the first position, the latching flange is removable from a corresponding one pair of mounting holes. In the second position, the curling edge abuts against the circuit board for preventing the card bracket from detaching from the circuit board.

### BACKGROUND

1. Technical Field

The present disclosure relates to an electronic device with a card bracket.

2. Description of Related Art

Electronic device can include a circuit board, a card bracket mounted on the circuit board, and a smart card mounted in the card bracket. The card bracket is typically secured to the circuit board by screws, which is inconvenient.

Therefore, there is room for improvement in the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an isometric, exploded view of an electronic device with a card bracket in accordance with an embodiment.

FIG. 2 is an assembled view of the electronic device of FIG. 1.

FIG. 3 is similar to FIG. 2, but viewed from another aspect.

FIG. 4 is a cross sectional view taken along line IV-IV of FIG. 3.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

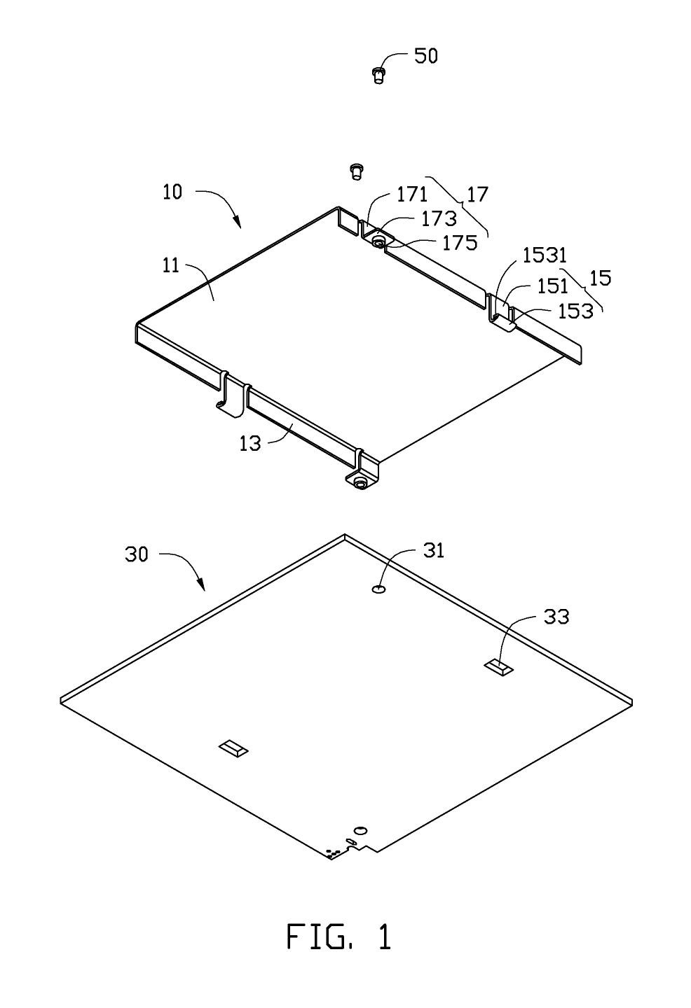

FIG. 1 shows an embodiment of an electronic device of the disclosure. The electronic device includes a card bracket 10 and a circuit board 30.

The card bracket 10 includes a base panel 11 and a pair of side flanges 13 extending substantially perpendicularly from opposite sides of the base panel 11. Each of the pair of side flanges 13 includes a mounting piece 17 and a latching piece 15. The latching piece 15 includes a resilient arm 151 extending substantially perpendicularly from the base panel 11 and a latching flange 153 extending outwardly from a distal end of the resilient arm 151. The latching flange 153 includes a curling edge 1531. An angle between the resilient arm 151 and the latching flange 153 is slightly less than 90 degrees. A length of the resilient arm 151 along a vertical direction perpendicular to the base panel 11 is greater than a width of each of the pair of side flanges 13. The mounting piece 17 includes a connecting portion 171 extending substantially perpendicularly from the base panel 11 and a mounting portion 173 extending outwardly and perpendicularly from the connecting portion 171. A mounting post 175 protrudes from the mounting portion 173. A length of the connecting portion 171 along the vertical direction is equal to the width of each of the pair of side flanges 13. The connecting portion 171 and the resilient arm 151 lie in the same plane as the corresponding side flange 15.

A pair of circular holes 31 is defined in the circuit board 30 corresponding to the mounting post 175. A pair of mounting holes 33 is defined in the circuit board 30 corresponding to the latching flange 153. Each of the pair of mounting holes 33 has a rectangular shape. A length of each of the pair of mounting holes 33 is substantially equal to a width of the latching piece 15. A width of each of the pair of mounting holes 33 is substantially equal to a width of the latching flange 153 along a horizontal direction perpendicular to each of the pair of side flanges 13.

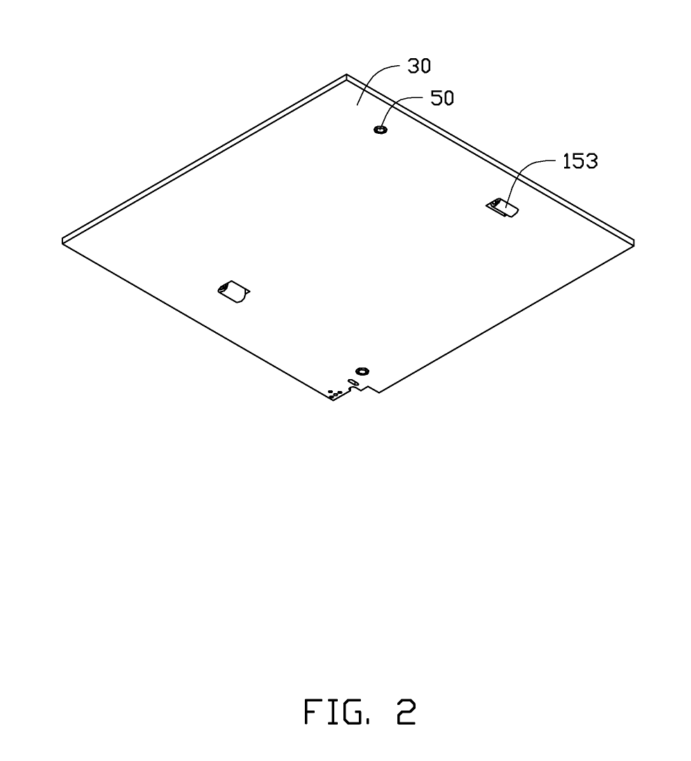

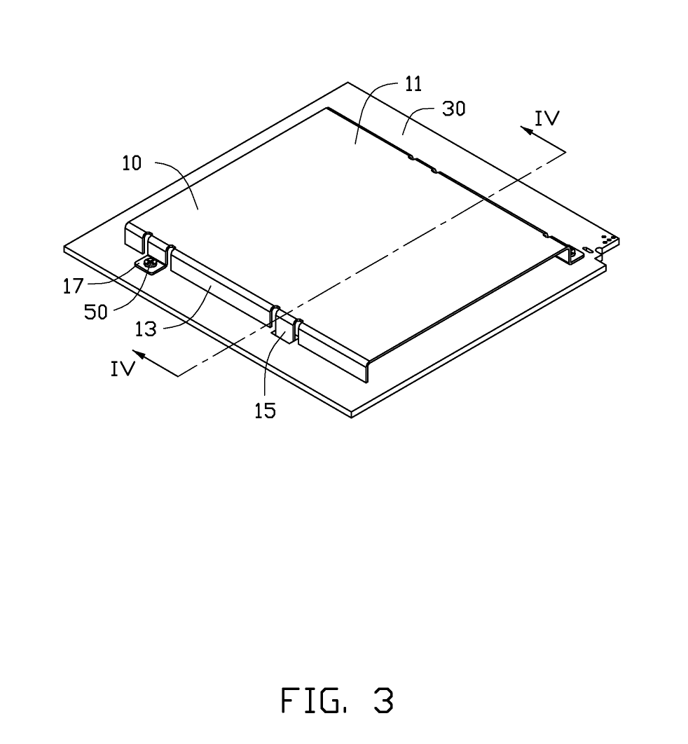

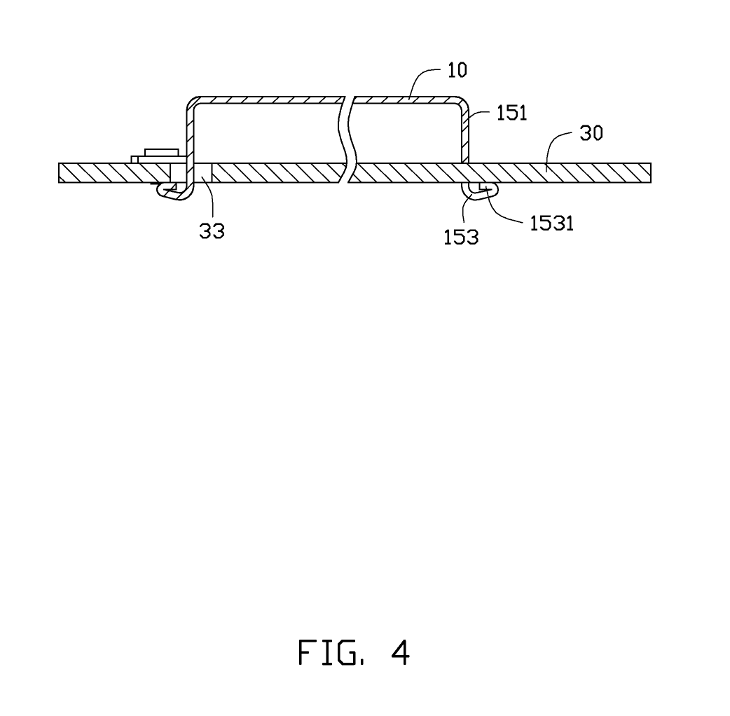

FIGS. 2 to 4 show in assembly, the mounting post 175 is aligned with a corresponding one of the pair of circular holes 31. The latching flange 153 is aligned with a corresponding one of the pair of mounting holes 33. The card bracket 10 is moved towards the circuit board 30. The mounting post 175 is received in the corresponding one of the pair of circular holes 31. The resilient arm 151 is deformed inwardly. The latching flange 153 is inserted into the corresponding one of the pair of mounting holes 33. When the latch flange 153 is extended through the corresponding one of the pair of mounting holes 33, the resilient arm 151 resumes to its original state. The curling edge 1531 abuts against the circuit board 30 for preventing the card bracket 10 moving away from the circuit board 30. A fastener 50 is secured to a hole in the mounting post 175. The card bracket 10 is fixed to the circuit board 30.

To detach the card bracket 10 from the circuit board 30, the fastener 50 is detached from the mounting post 175. The resilient arm 151 is deformed inwardly and the latching flange 153 is disengaged from the corresponding one of the pair of mounting holes 33. The mounting post 175 is disengaged from the corresponding one of the pair of circular holes 31. The card bracket 10 is detached from the circuit board 30.

It is to be understood, however, that even though numerous characteristics and advantages have been set forth in the foregoing description of embodiments, together with details of the structures and functions of the embodiments, the disclosure is illustrative only and changes may be made in detail, especially in matters of shape, size, and arrangement of parts within the principles of the disclosure to the full extent indicated by the broad general meaning of the terms in which the appended claims are expressed.

What is claimed is:

1. An electronic device comprising:
a card bracket comprising a base panel and a pair of side flanges extending substantially perpendicularly from opposite sides of the base panel; and each of the pair of side flanges comprising a latching piece and a mounting piece, the latching piece comprising a resilient arm extending substantially perpendicularly from the base panel and a latching flange extending from the resilient arm, and the mounting piece comprising a connecting portion extending substantially perpendicularly from the base panel, a mounting portion extending substantially perpendicularly from the connecting portion, and a mounting post protruding from the mounting portion; and
a circuit board comprising a circular hole corresponding to the mounting post and a mounting hole corresponding to the latching flange;
wherein the mounting post is engaged with the circular hole, and the resilient arm is deformable and movable between a first position and a second position, in the first position, the latching flange is removable from the mounting hole; and in the second position, the latching flange abuts against the circuit board for preventing the card bracket from detaching from the circuit board.

2. The electronic device of claim 1, wherein the latching flange extends outwardly from a distal end of the resilient arm at an angle less than 90 degrees.

3. The electronic device of claim 1, wherein the latching flange comprises a curling edge, in the second position, the curling edge abuts against the circuit board for preventing the card bracket from detaching from the circuit board.

4. The electronic device of claim 1, wherein a length of the resilient arm along a vertical direction perpendicular to the base panel is greater than a width of each of the pair of side flanges.

5. The electronic device of claim 1, wherein a length of the connecting portion along a vertical direction perpendicular to the base panel is equal to a width of each of the pair of side flanges.

6. The electronic device of claim 1, wherein the connecting portion and the resilient arm lie in the same plane as the corresponding one of the pair of side flanges.

7. The electronic device of claim 6, wherein the mounting hole has a rectangular shape, a length of the mounting hole is substantially equal to a width of the latching piece, and a width of the mounting hole is substantially equal to a width of the latching flange along a horizontal direction perpendicular to each of the pair of side flanges.

8. An electronic device comprising:
a card bracket comprising a base panel and a pair of latching pieces extending from opposite sides of the base panel; each of the pair of latching pieces comprising a resilient arm extending substantially perpendicularly from the base panel and a latching flange extending from the resilient arm at an angle slightly less than 90 degrees; the latching piece comprises a curling edge; and
a circuit board comprising a pair of mounting holes corresponding to the pair of latching flanges;
wherein the resilient arm is deformable and movable between a first position and a second position, in the first position, the latching flange is removable from a corresponding one pair of mounting holes; and in the second position, the curling edge abuts against the circuit board for preventing the card bracket from detaching from the circuit board.

9. The electronic device of claim 8, wherein the card bracket further comprises a pair of mounting pieces extending from opposite sides of the base panel, each of the pair of mounting pieces comprises a connecting portion extending substantially perpendicularly from the base panel and a mounting portion extending substantially perpendicularly from the connecting portion and secured to the circuit board.

10. The electronic device of claim 9, wherein a mounting post protrudes from the mounting portion, a circular hole is defined in the circuit board for receiving the mounting post, and a fastener is secured to the mounting post to secure the card bracket to the circuit board.

11. The electronic device of claim 9, wherein a length of the connecting portion along the vertical direction is equal to a width of each of the pair of side flanges.

12. The electronic device of claim 9, wherein the connecting portion and the resilient arm lie in the same plane as the corresponding one of the pair of side flanges.

13. The electronic device of claim 8, wherein a length of the resilient arm along a vertical direction perpendicular to the base panel is greater than a width of each of the pair of side flanges.

14. The electronic device of claim 8, wherein each of the pair of mounting holes has a rectangular shape, a length of each of the pair of mounting holes is substantially equal to a width of the latching piece, and a width of each of the pair of mounting holes is substantially equal to a width of the latching flange along a horizontal direction perpendicular to the resilient arm.
